(19) United States
(12) Patent Application Publication
(10) Pub. No.: US 2020/0168749 A1
(43) Pub. Date: May 28, 2020

(54) EDGE-INCIDENT LIGHT RECEIVING ELEMENT

(71) Applicant: KYOTO SEMICONDUCTOR CO., LTD., Kyoto-shi, Kyoto (JP)

(72) Inventors: Yuichi NISHIMURA, Kyoto-shi, Kyoto (JP); Etsuji OMURA, Kyoto-shi, Kyoto (JP)

(21) Appl. No.: 16/611,283

(22) PCT Filed: Jul. 25, 2017
(86) PCT No.: PCT/JP2017/026791

§ 371 Date: Nov. 6, 2019

(51) Int. Cl. H01L 31/0232; H01L 31/0352

(52) U.S. Cl. CPC H01L 31/02327; H01L 31/035281

(57) ABSTRACT

An edge-incident light receiving element is equipped with a light receiving portion formed near a first surface of a semiconductor substrate, a concave reflective portion formed at a second surface of the semiconductor substrate that opposes the first surface, and a planar reflective portion formed between the first surface and the second surface, and the planar reflective portion reflects incident light on an edge surface of the semiconductor substrate that is perpendicular to the first surface and to the second surface toward the concave reflective portion, and the concave reflective portion reflects the incident light reflected by the planar reflective portion so as to condense on the light receiving portion.

### TECHNICAL FIELD

The present invention relates to an edge-incident light receiving element having a reflection mechanism that causes the optical path of incident light to be bent in the interior of the light receiving element, and in particular relates to an edge-incident light receiving element that is capable of high speed operation at 25 GHz or higher.

### BACKGROUND ART

Along with the development of high speed high capacity communication networks in recent years, the response speed demanded from light emitting elements and light receiving elements for optical communication employed in optical trunk systems has come to exceed 25 GHz. Due to this, the area of the light absorption region in light receiving elements has been getting smaller, in order to enable high speed operation by reducing the junction capacitance of the PN junction that constitutes the light absorption region of the light receiving portion. For example, in order to obtain a response speed of 25 GHz, it is necessary to make the dimensions of the light absorption region around 20 μm×20 μm.

Light receiving elements of this type may be roughly classified into two types: the planar-incident light receiving type and the edge-incident light receiving type. A light receiving element of the planar-incidence type is one with which, with respect to a light absorption region that is formed on a main surface of a semiconductor substrate, light is incident approximately perpendicularly to the main surface of the semiconductor substrate, and this is a currently mainstream type of light receiving element. On the other hand, an edge-incident light receiving element, as for example described in Patent Document #1, is one in which, with respect to a light absorption region that is formed on a main surface of a semiconductor substrate, light is incident from an edge surface of the semiconductor substrate in a direction parallel to the main surface of the semiconductor substrate.

With a receiver module that is equipped with a light receiving element for optical communication, the output end of an optical fiber is fixed in the receiver module, an optical signal emitted from the output end is incident on the light receiving element, and an electrical signal is outputted by electric current due to electron hole pairs generated in the light absorption region by the incident light. Due to constraints on fixing the optical fiber in the receiver module, the light receiving element is often arranged so that the main surface of the semiconductor substrate is perpendicular with respect to the mounting substrate of the receiver module. For this reason, a light receiving element of the planar-incident light receiving type requires a mounting sub carrier but a light receiving element of the edge-incident light receiving type does not require such a sub carrier, and accordingly in recent years the latter has attracted attention from the standpoint of ease of assembly and reduction of manufacturing cost.

### PRIOR ART DOCUMENTS

### Patent Documents

Patent Document #1: Japanese Laid-Open Patent Publication Heisei 11-087760.

### SUMMARY OF THE INVENTION

### Technical Problem

As described above, with a light receiving element of the edge-incident light receiving type, light is incident parallel to the light receiving portion of the semiconductor substrate main surface. Since the depth of the light absorption region of the light receiving portion is small as compared to the size of the light absorption region in the direction parallel to the semiconductor substrate main surface, accordingly, with an edge-incident light receiving element, the light reception area for incident light is small as compared to the case of a planar-incident light receiving element. In order to compensate for such a small light reception area, the edge-incident light receiving element of Patent Document #1 is structured so as to ensure reception of a sufficient amount of light by making the incident light be reflected by the edge surface of the light absorption region, thus making the optical path through the light absorption region longer. However, when the area of the light absorption region is reduced in order to enable high speed operation as described above, it becomes impossible to extract sufficient electrical current, since the optical path through the light absorption region becomes shorter and the amount of light received is reduced. Due to this, it is difficult to increase the speed by reducing the area of the light absorption region of the light receiving portion.

On the other hand, as shown in FIG. 12, an edge-incident light receiving element 50 is per se known that incorporates a reflective surface 54 that reflects incident light on an edge surface 52 of a semiconductor substrate 51 so that the light is incident in the depth direction on a light receiving portion 53 that is provided with a light absorption region. The reflective surface 54 is built so that the light is incident at an angle of incidence that is larger than the critical angle, which is determined by the semiconductor substrate and by the material outside it, and accordingly the incident light is totally reflected by the reflective surface 54 toward the light receiving portion 53. The light receiving portion 53 has a light reception area of around 100 μm×100 μm, and is built to be capable of ensuring a sufficient amount of received light.

However, the light emitted from the output end of the optical fiber spreads out in the shape of a cone having an apex angle of around 12°, and, although this angle becomes smaller according to the law of refraction when the light is incident on the edge surface 52 of the semiconductor substrate 51, the incident light still spreads out in the shape of a cone within the semiconductor substrate 51 as well. Since the irradiation range corresponding to the base surface of this cone becomes wider as the light progresses within the semiconductor substrate, accordingly, when the light receiving portion 53 is formed to be small, it becomes difficult to obtain a sufficient amount of received light because the light reception area is reduced. For this reason, increase of the speed of the edge-incident light receiving element 50 by reduction of the size of the light receiving portion 53 cannot be anticipated. Moreover, when the light receiving portion 53 is made small, if some deviation occurs in the position where the output end of the optical fiber is fixed due to some variation during assembly of the receiver module, then the position of the incident light shifts, and accordingly there is a possibility that the amount of light received will be reduced yet further.

The object of the present invention is to provide an edge-incident light receiving element that is capable of high speed operation.

### Means to Solve the Problems

The present invention presents an edge-incident light receiving element wherein comprises a light receiving portion formed near a first surface of a semiconductor substrate, a spherical cap-shaped concave reflective portion formed at a second surface of the semiconductor substrate that opposes the first surface and formed circularly in plan view in a direction perpendicular to the second surface, and a planar reflective portion formed between the first surface and the second surface, and wherein: the planar reflective portion constituted so as to reflect incident light entered perpendicularly on an edge surface of the semiconductor substrate that is perpendicular to the first surface and to the second surface toward the spherical cap-shaped concave reflective portion; and the spherical cap-shaped concave reflective portion is constituted so as to reflects the incident light reflected by the planar reflective portion so as to condense on the light receiving portion.

Accordingly, since the planar reflective portion reflects incident light on the edge surface of the semiconductor substrate toward the concave reflective portion of the second surface, and the concave reflective portion reflects this light so as to condense on the light receiving portion near the first surface, accordingly it is possible to reduce the size of the light receiving portion while still ensuring reception of a sufficient amount of light, so that it is possible to increase the speed of the edge-incident light receiving element by reducing the size of the light receiving portion. Moreover, since the concave reflective portion condenses the light on the light receiving portion, accordingly it is possible to suppress decrease of the amount of received light due to deviation of the position of incidence of the incident light.

In a preferable first aspect, the planar reflective portion is connected to the second surface at an acute angle.

Accordingly, the planar reflective portion is able to reflect incident light on the edge surface of the semiconductor substrate toward the concave reflective portion of the second surface of the semiconductor substrate.

In a preferable second aspect, the planar reflective portion is connected to the second surface at an obtuse angle.

Accordingly, the planar reflective portion is able to reflect incident light on the edge surface of the semiconductor substrate toward the concave reflective portion of the second surface of the semiconductor substrate.

### Advantages of the Invention

According to the edge-incident light receiving element of the present invention, high speed operation is possible even though the light absorption region is smaller.

### BRIEF DESCRIPTION OF THE DRAWINGS

FIG. 1 is a plan view of an edge-incident light receiving element according to a first embodiment of the present invention;

FIG. 2 is a sectional view of FIG. 1 along lines II-II;

FIG. 3 is a figure showing the optical path of incident light in FIG. 2;

FIG. 4 is a sectional view showing a diffused layer formed on a semiconductor substrate;

FIG. 5 is a sectional view showing a light receiving portion formed on the semiconductor substrate;

FIG. 6 is a sectional view showing a circular groove formed on the semiconductor substrate;

FIG. 7 is a sectional view showing a convex portion formed on the semiconductor substrate;

FIG. 8 is a sectional view showing an etching mask for making a groove portion to be formed on the semiconductor substrate;

FIG. 9 is a sectional view showing the groove portion formed on the semiconductor substrate of FIG. 8;

FIG. 10 is a figure showing the amounts of light received by the light receiving portion according to the position of incidence of the incident light in FIG. 3;

FIG. 11 is a sectional view of an edge-incident light receiving element according to a second embodiment of the present invention; and

FIG. 12 is a sectional view of edge-incident light receiving element according to the prior art.

### DESCRIPTION OF EMBODIMENTS

Now, the present invention will be explained on the basis of an embodiment thereof.

### First Embodiment

First, the overall structure of an edge-incident light receiving element will be explained.

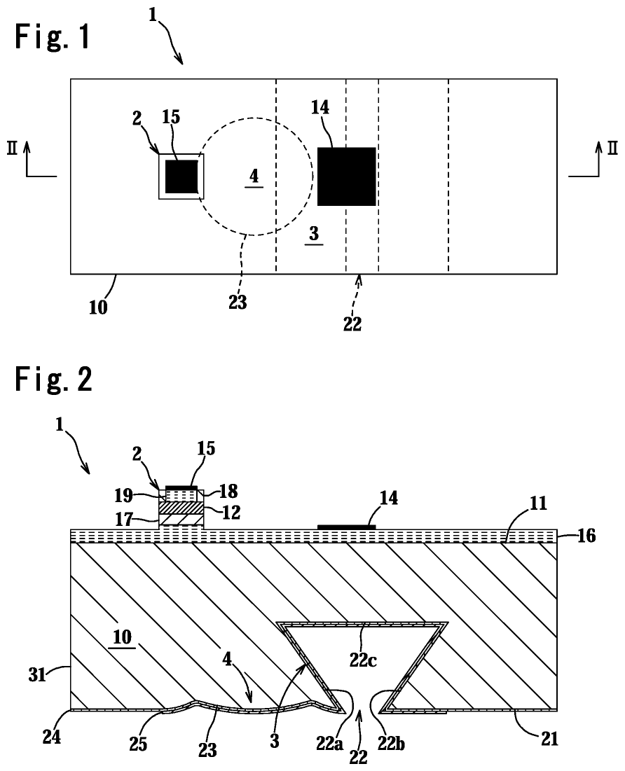

As shown in FIG. 1 through FIG. 3, taking a plane orientation (100) of a semiconductor substrate 10 as its upper surface 11, an edge-incident light receiving element 1 incorporates a light receiving portion 2 which includes a light absorption region consisting of an i type InGaAs layer 12 near its upper surface 11 (this is “first surface”), with a substrate electrode 14 (an n electrode) being provided on the upper surface 11 of the semiconductor substrate 10, while a light receiving portion electrode 15 (a p type electrode) is provided on the upper surface of a p type diffusion region 19 of the light receiving portion 2. Although here the semiconductor substrate 10 is a semi insulating InP substrate, depending on the application for the edge-incident light type light receiving element 1, a substrate material such as an Si substrate may be selected as appropriate. An InP substrate is transparent to infrared light having wavelength longer than 1 μm, so that infrared light having wavelength longer than 1 μm that is incident on the InP substrate progresses within the InP substrate.

The cross section of a groove portion 22 that opens to the lower surface 21 (this is “second surface”) of the semiconductor substrate 10 opposite to its upper surface 11 is formed in a dovetail shape by a first inclined surface 22a and a second inclined surface 22b each of which forms an acute angle with the lower surface 21, and by a top surface 22c substantially parallel to the upper surface 11 and the lower surface 21 of the semiconductor substrate 10. Here, the first inclined surface 22a is that inclined surface of the groove portion 22 that is closer to the light receiving portion 2. The first inclined surface 22a and the second inclined surface 22b are on plane orientation {111} of the semiconductor substrate 10, and the plane orientation (100) meets each of plane orientation {111} of the first and second inclined surfaces 22a,22b at an angle of about 54.7°.

In the neighborhood of the first inclined surface 22a, the lower surface 21 of the semiconductor substrate 10 is further provided with a convex portion 23 that is formed so as to be convex downward in a part spherical shape.

An edge face 31 that is approximately perpendicular to the upper surface 11 and to the lower surface 21 of the semiconductor substrate 1 and that is on the convex portion 23 side with respect to the groove portion 22 is formed to extend approximately parallel to the direction in which the groove portion 22 extends, and light emitted from the optical fiber is incident on the edge surface 31. The edge surface 31 is formed flat, in order to prevent scattering of the incident light. Moreover, the edge surface 31 may be provided with a reflection prevention layer for suppressing reflection of the incident light.

The first inclined surface 22a and the convex portion 23 incorporate a dielectric layer 24 (for example, a silicon nitride layer or a silicon oxide layer) and a metallic layer 25 (for example a silver layer or a gold layer) for reflecting incident light, and thus constitute a planar reflective portion 3 and a spherical cap-shaped concave reflective portion 4, respectively. Here, the refractive index of the InP substrate and the silicon nitride layer for incident light of wavelength of, for example, 1.3 μm may respectively be about 3.2 and about 2.0, so that, according to Snell's law, the critical angle becomes about 37.3°.

Additionally, the spherical cap-shaped concave reflective portion 4 is formed circularly in plan view in a direction perpendicular the lower surface 21.

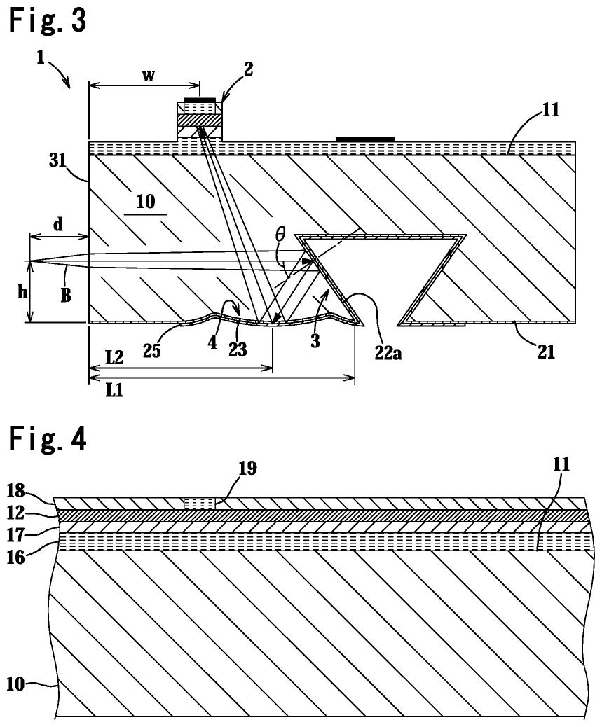

As shown in FIG. 3, the optical axis of the incident light B that is incident on the edge surface 31 and that progresses parallel to the upper surface 11 and the lower surface 21 is incident on the planar reflective portion 3 at an angle of incidence θ=35.3° which is close to the critical angle, and accordingly the greater portion of the incident light is reflected toward the concave reflective portion 4. It would also be possible to arrange for the critical angle to be small so that the incident light is totally internally reflected by the planar reflective portion 3, by selecting the dielectric layer 24 to have small refractive index, or by making the first inclined surface 22a as a planar reflective portion 3 that is not provided with any metallic layer 25 or dielectric layer 24.

The outer diameter and the radius of curvature of the convex portion 23 are set appropriately to values that can condense light on the light receiving portion 2, according to the size of the edge-incident light receiving element 1. If the distance between the light receiving portion 2 and the lower surface 21 of the semiconductor substrate 10 is 150 μm, the distance L1 from the edge surface 31 to the bottom edge of the first inclined surface 22a is 180 μm, the distance L2 from the edge surface 31 to the center of the convex portion 23 is 125 μm, the distance w from the edge surface 31 to the center of the light receiving portion 2 is 70 μm, and the incident light is emitted from a position whose distance h from the lower surface 21 of the semiconductor substrate 10 is 50 μm and whose distance d from the edge surface 31 is 50 μm, then, by setting the external diameter of the convex portion 23 to be 80 μm and its radius of curvature to be 320 μm, it is possible to condense the incident light to a light receiving section 2 that is rectangular in plan view and has a side of 20 μm, or that is circular in plan view and has an external diameter of 20 μm.

As shown in FIG. 2 and FIG. 4, a first n type InP layer 16 is formed uniformly on the upper surface 11 of the semiconductor substrate 10, and the light receiving portion 2 that receives incident light reflected by the planar reflective portion 3 and by the concave reflective portion 4 is formed over the layer 16. The light receiving portion 2 has, in order from the side of the first n type InP layer 16, a second n type InP layer 17, an i type InGaAs layer 12 (i.e. a light absorption region), and a third n type InP layer 18, and has a p type diffusion region 19 within the third n type InP layer 18, so as to form a pin photodiode. The portions on the upper surface side of the semiconductor substrate 10 apart from the substrate electrode 14 and the light receiving portion electrode 15 may be covered over with a protective layer (for example, a dielectric layer made from silicon nitride) for protecting the edge-incident light type light receiving element 1 from moisture.

Next, a method of manufacturing the edge-incident light receiving element 1 will be explained.

As shown in FIG. 4, on a clean semiconductor substrate 10 (a semi insulating InP substrate) having a plane orientation (100) as its main surface (i.e. its upper surface 11), in order, a first n type InP layer 16, a second n type InP layer 17, an i type InGaAs layer 12, and a third n type InP layer 18 are formed by a vapor deposition method or the like. Although this feature is not shown in the figures, a mask layer (for example, a silicon nitride layer) is formed with an opening so as to expose a predetermined region of the third n type InP layer 18, and a p type diffusion region 19 is formed by a selective diffusion method, for example by diffusing zinc. The thicknesses of the first n type InP layer 16, the second n type InP layer 17, the i type InGaAs layer 12, and the third n type InP layer 18 are respectively around 5 μm, 2 μm, 1 μm, and 2 μm, and the width of the p type diffusion region 19 is around 20 μm.

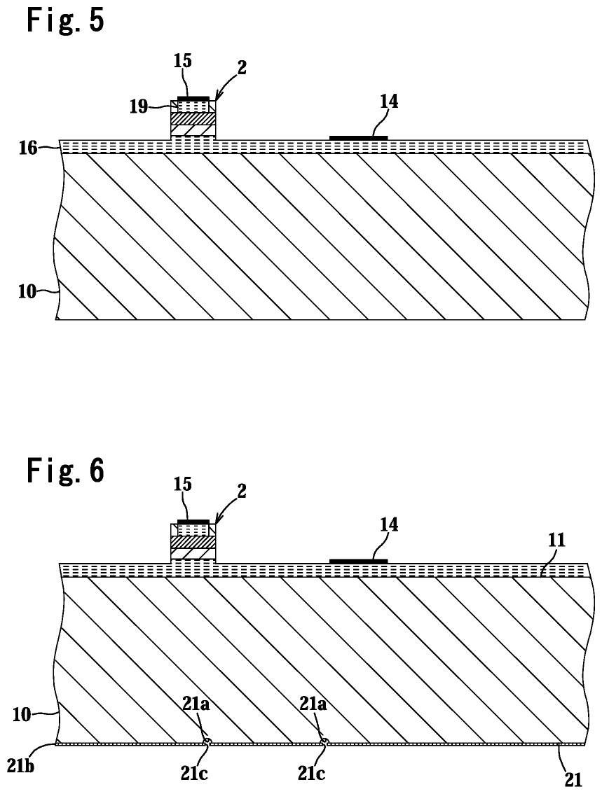

Next, as shown in FIG. 5, the third n type InP layer 18, the I type InGaAs layer 12, and the second n type InP layer 17 are removed by a selective etching method so as to expose the first n type InP layer 16, while leaving predetermined portions thereof including the p type diffusion region 19, and thereby the light receiving portion 2 is formed. At this time, the first n type InP layer 16 is also made thinner by its upper surface being etched. Although this is not shown in the figures, a protective layer (for example a dielectric layer made of silicon nitride) is formed, and this protective layer is partially opened by a selective etching method. Furthermore, a metallic layer is formed by a vacuum vapor deposition method, and, except for regions of a substrate electrode 14 and a light receiving portion electrode 15, the metallic layer is removed by a selective etching method. It would also be possible to form the light receiving portion 2 after having formed the light receiving portion electrode 15, and to form the substrate electrode 14 subsequently.

The metallic layer that is to become the electrodes is a metallic layer of a laminated structure and has a chromium layer, a nickel layer, or the like as an adhesion layer between the p type diffusion region 19 and the first n type InP layer 16, and may be connected to terminals of the mounting substrate by wire bonding. Moreover, although this is not shown in the figures, in order to protect the upper surface 11 of the semiconductor substrate 10 on which the light receiving portion 2 have been formed in the subsequent processes, a photo resist layer is thickly deposited thereupon.

Next, as shown in FIG. 6, a groove 21a that is approximately circular in plan view and that has external diameter around 80 μm and depth around 5 μm is formed by a selective etching method on the lower surface 21 of the semiconductor substrate 10 that is opposite to its upper surface 11 on which the light receiving portion 2 are formed. For example, as an etching mask, an opening portion 21c that is circular in plan view and via which the lower surface 21 of the semiconductor substrate 10 is exposed may be formed in the silicon nitride layer 21b that has been formed on the lower surface 21 of the semiconductor substrate 10, and the lower surface 21 of the semiconductor substrate 10 may be etched by a per se known etching solution whose anisotropy is low or which is isotropic. The circular groove 21a is formed on the lower surface of the semiconductor substrate 10 in this manner. At this time, the position at which the circular groove 21a is formed is set in consideration of the plane orientation [110] in which the groove portion 22 to be formed in the subsequent process should extend.

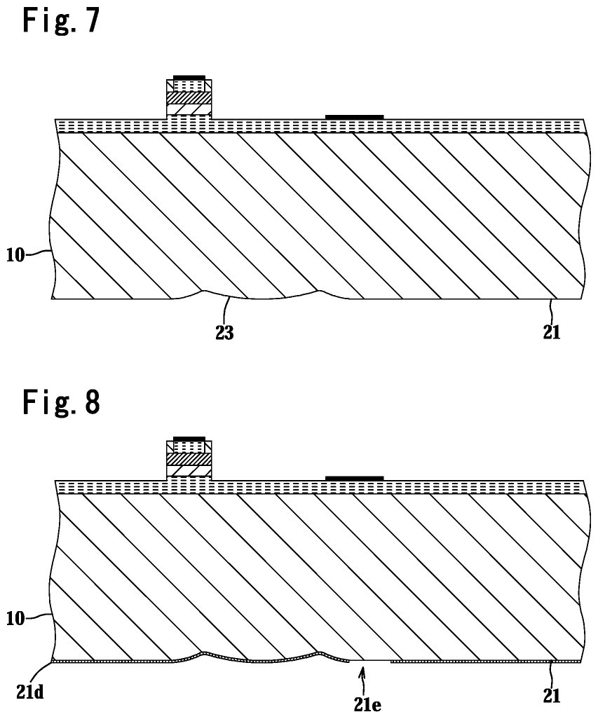

Next, the etching mask is removed, and the lower surface 21 of the semiconductor substrate 10 is etched with a per se known etching solution whose anisotropy is low or which is isotropic. In the vicinity of the opening portion of the circular groove 21a, the speed of etching is high as compared with the flat regions on the lower surface of the semiconductor substrate 10 where the etching proceeds from one direction, since here the etching proceeds from two directions, i.e. both within the circular groove 21a and also along the lower surface 21 of the semiconductor substrate 10. Due to this, as shown in FIG. 7, a convex portion 23 having a curved surface shaped as a bulge is formed on the region interior to the circular groove 21a. And, since the etching speed is faster in the neighborhood of the opening portion of the circular groove 21a than outside the circular groove 21a, accordingly the curved surface comes to be formed so as to connect smoothly from the circular groove 21a to a flat region.

Next, an etching mask for forming the groove portion 22 that opens to the lower surface 21 of the semiconductor substrate 10 is formed. As shown in FIG. 8, for example, an opening portion 21e of length around 200 μm in the direction in which the groove portion 22 is to extend and of width around 20 μm is formed in the silicon nitride layer 21d formed on the lower surface of the semiconductor substrate 10, so that the lower surface 21 of the semiconductor substrate 10 is exposed.

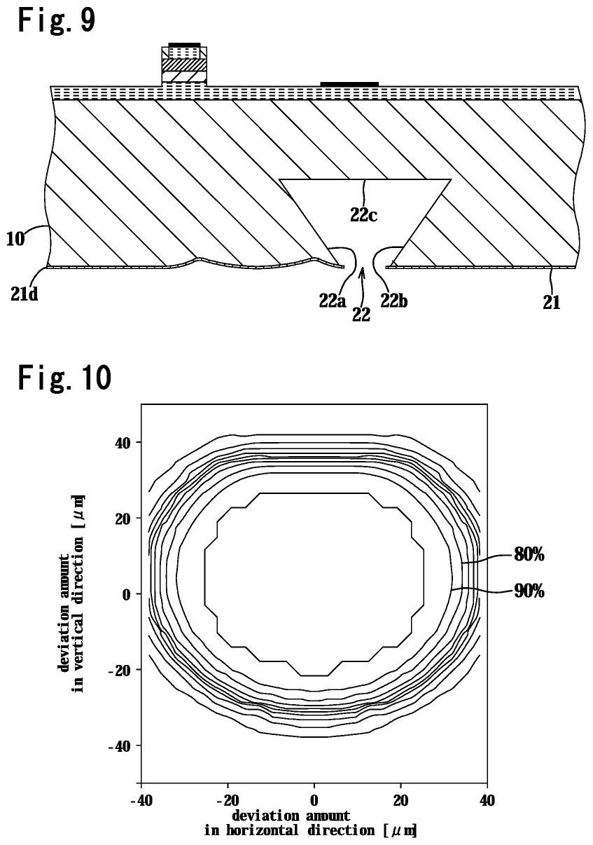

Next, as shown in FIG. 9, after the groove portion 22 has been etched to a predetermined depth (for example to a depth of 80 μm) by employing a per se known etching solution having anisotropy that depends on the crystal plane orientation (for example a bromomethanol solution whose etching speed on the plane orientation {111} is slow), the silicon nitride layer 21d of the etching mask is removed. In this manner, the dovetail shape groove portion 22 having the first inclined surface 22a, the second inclined surface 22b, and the top surface 22c is formed. The first inclined surface 22a and the second inclined surface 22b are on plane orientation {111}, and intersect both the top surface 22c of the groove portion 22 and also the lower surface 21 of the semiconductor substrate 10 at angles of around 54.7°.

Next, in order for the first inclined surface 22a and the convex portion 23 to reflect incident light, a dielectric layer 24 (for example, a silicon nitride layer) and a metallic layer 25 (for example a silver layer or a gold layer) are formed in order by, respectively, a vapor deposition method and a vacuum vapor deposition method at respective thicknesses of, for example, 0.2 μm and 1 μm, and thereby a concave reflective portion 4 is formed on the convex portion 23 and a planar reflective portion 3 is formed on the first inclined surface 22a. The metallic layer 25 may be removed in regions other than the convex portion 23 and the first inclined surface 22a.

And, next, the photoresist layer that protects the upper surface 11 of the semiconductor substrate 10 is removed and the semiconductor substrate 10 with the light receiving portion 2, the concave reflective portion 4, and the planar reflective portion 3 formed thereon is diced into a predetermined shape, whereby the edge-incident light receiving element 1 shown in FIG. 1 and FIG. 2 is obtained. A process for flattening the edge surface 31 on which light is incident in order to prevent scattering of incident light, and a process of layer formation thereon in order to prevent reflection of incident light, may also be implemented.

The operation and the beneficial effects provided by the edge-incident light receiving element 1 according to the first embodiment will now be explained.

The results of simulation of the arrival rate of incident light to the light receiving portion 2 (i.e. the light receiving portion arrival ratio) when the position of incidence of the incident light is varied in the vertical direction and in the horizontal direction (i.e. in the depth direction) in FIG. 3 are shown in FIG. 10. Although the light receiving portion 2 is formed over an area that in plan view is a rectangle 20 μm on a side or a circle having external diameter of 20 μm, which is smaller than in the prior art, it is still possible to obtain a light receiving portion arrival ratio that is 90% or greater even when the position of incidence deviates by ±20 μm in the vertical direction or in the horizontal direction from the position in which the incident light is incident on the center of the light receiving portion 2. Since thus, even if the light receiving portion 2 is small, the incident light can be reliably condensed by the concave reflective portion 4 and condensed to the light receiving portion 2, accordingly it is possible to increase the speed of the edge-incident light receiving element 1 by shrinking down the light receiving portion 2, and positional alignment becomes easy when fixing the output end of an optical fiber to a receiver module that is equipped with this edge-incident light receiving element 1.

### Second Embodiment

An edge-incident light receiving element 1A according to a second embodiment in which the edge-incident light receiving element 1 of the first embodiment is partially altered will now be explained. The same reference symbols are appended to portions that are the same as in the first embodiment, and explanation thereof will be omitted.

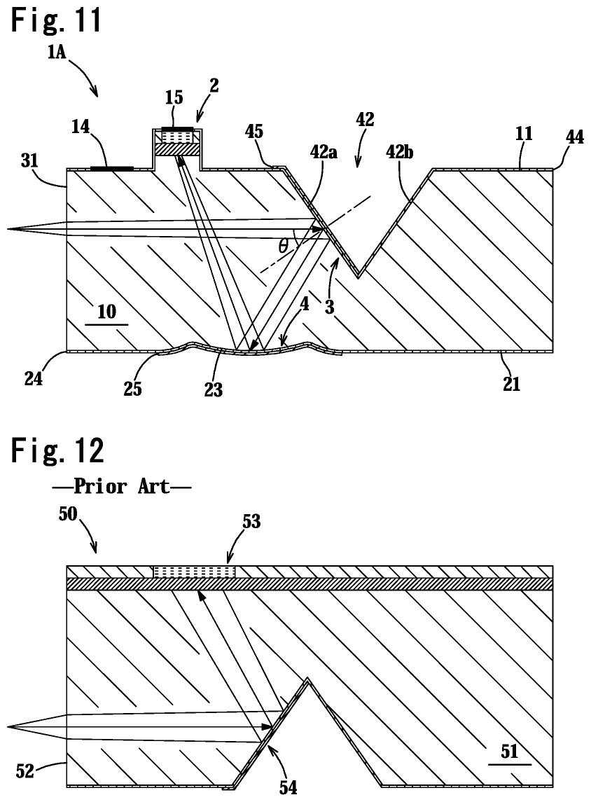

As shown in FIG. 11, taking a plane orientation (100) of a semiconductor substrate 10 as its upper surface 11 (this is “first surface”), the edge-incident light receiving element 1A has a light receiving portion 2 near its upper surface 11, with a substrate electrode 14 (an n electrode) being provided on the upper surface 11 of the semiconductor substrate 10 and a light receiving portion electrode 15 (a p electrode) being provided on the light receiving portion 2. A letter V shaped groove portion 42 is provided on the upper surface 11 and is defined by a third inclined surface 42a and a fourth inclined surface 42b, each of which connects to the upper surface 11 at an obtuse angle of around 125.3°. The third inclined surface 42a and the fourth inclined surface 42b are on plane orientation {111}, and the apical angle of the letter V shaped groove portion 42 defined by the third inclined surface 42a and the fourth inclined surface 42b is around 70.6°. The third inclined surface 42a incorporates a dielectric layer 44 (for example, a silicon nitride layer or a silicon oxide layer) and a metallic layer 45 (for example a silver layer or a gold layer) for reflecting incident light, and thus constitutes a planar reflective portion 3. The third inclined surface 42a that does not incorporate any dielectric layer 44 or metallic layer 45 could also be employed as the planar reflective portion 3.

Moreover, a convex portion 23 that is formed so as to bulge downward is formed on the lower surface 21 of the semiconductor substrate 10, between the letter V shaped groove portion 42 and the light receiving portion 2 in plan view. The convex portion 23 is provided with a dielectric layer 24 and a metallic layer 25, and constitutes a spherical cap-shaped concave reflective portion 4 that is formed in the shape of a concave surface facing toward the upper surface 11.

An edge surface 31 that is substantially perpendicular to the upper surface 11 and to the lower surface 21 of the semiconductor substrate 10 on the side of the light receiving portion 2 with respect to the letter V shaped groove portion 42 is the surface on which light is incident, and is formed in a direction approximately parallel to the direction in which the letter V shaped groove portion 42 extends.

The letter V shaped groove portion 42 is formed by etching the upper surface 11 of the semiconductor substrate 10, and by employing a method similar to that employed for the groove portion 22 in the first embodiment and using a per se known etching solution whose anisotropy depends on the crystal plane orientation. However, the light receiving portion 2 and the spherical cap-shaped concave reflective portion 4 are arranged in consideration of the fact that the direction in which the letter V shaped groove portion 42 extends is orthogonal to the direction in which the groove portion 22 of the first embodiment extends. The edge-incident light receiving element 1A formed in this manner is capable of condensing the incident light and leading it to the light receiving portion 2 in a similar manner to the edge-incident light receiving element 1 of the first embodiment, and provides the same beneficial effects.

### DESCRIPTION OF REFERENCE NUMERALS

1, 1A: edge-incident light receiving element
2: light receiving portion
3: planar reflective portion
4: spherical cap-shaped concave reflective portion
10: semiconductor substrate
11: upper surface (first face)
21: lower surface (second face)
22: groove portion
22a: first inclined surface
23: convex portion
31: edge surface
42: V shaped groove portion
42a: third inclined surface

1. An edge-incident light receiving element, wherein comprises a light receiving portion formed near a first surface of a semiconductor substrate, a spherical cap-shaped concave reflective portion formed at a second surface of the semiconductor substrate that opposes the first surface and formed circularly in plan view in a direction perpendicular to the second surface, and a planar reflective portion formed between the first surface and the second surface, and wherein:
the planar reflective portion is constituted so as to reflect incident light entered perpendicularly on an edge surface of the semiconductor substrate that is perpendicular to the first surface and to the second surface toward the spherical cap-shaped convave reflective portion; and
the spherical cap-shaped concave reflective portion is constituted so as to reflect the incident light reflected by the planar reflective portion so as to condense on the light receiving portion.

2. The edge-incident light receiving element according to claim 1, wherein the planar reflective portion is formed so as to connect to the second surface at an acute angle.

3. The edge-incident light receiving element according to claim 1, wherein the planar reflective portion is formed so as to connect to the second surface at an obtuse angle.
